(19) United States
(12) Patent Application Publication
(10) Pub. No.: US 2019/0013417 A1
(43) Pub. Date: Jan. 10, 2019

(54) Semiconductor engine driving technology for new electric vehicle

(71) Applicants: Haibiao Wang, Shanghai (CN); Jimmy Wang, Hillsborough, CA (US); Yuling Sun, Dalian (CN)

(72) Inventors: Haibiao Wang, Shanghai (CN); Jimmy Wang, Hillsborough, CA (US); Yuling Sun, Dalian (CN)

(21) Appl. No.: 16/105,992

(22) Filed: Aug. 21, 2018

(51) Int. Cl. H01L 29/92; H01L 29/16; H01L 29/167; H01L 29/43

(52) U.S. Cl. CPC H01L 29/92; H01L 29/43; H01L 29/167; H01L 29/1606

(57) ABSTRACT

A new semiconductor engine driving technology for an electric vehicle is provided. A working principle of the present invention is in a completely different way from conventional batteries because there is no battery stack like a normal battery. The reason is that during the charging and discharging process, reversible electrochemical reaction does not occurs on the electrode, but the flowing charged graphene polymer porous microspheres is entered into an ion membrane reaction cell and a semiconductor capacitor accumulator to generate a low voltage current. The semiconductor capacitor accumulator is formed by a plurality of PN junction films connected in series and parallel, and is connected with an electric motor to form an automobile engine to form a new capacitive driving circuit.

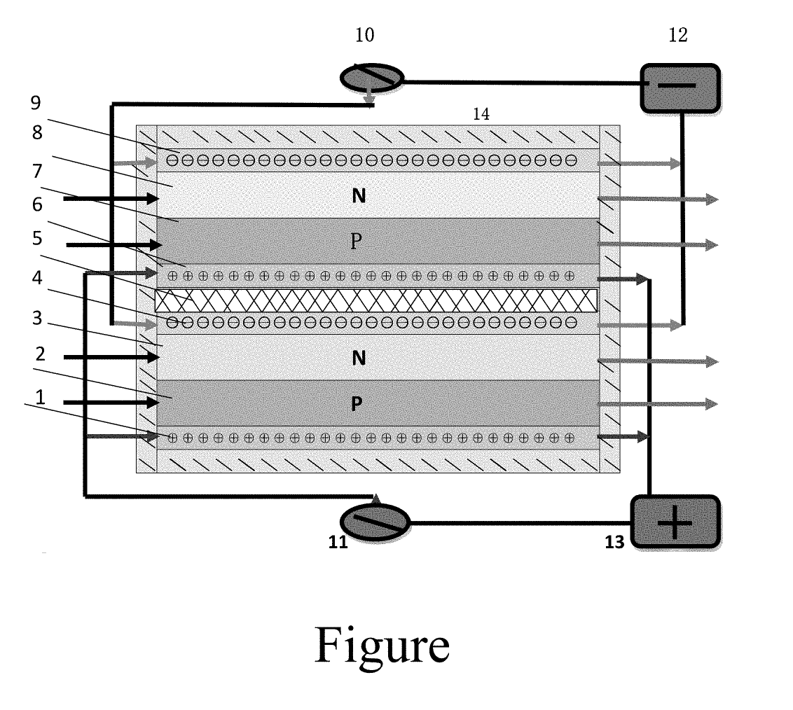

### BACKGROUND OF THE PRESENT INVENTION

### Field of Invention

The present invention relates to the technical field of the new energy applications of for automobile, and more particularly to a semiconductor engine driving technology for a new electric vehicle. The semiconductor engine invented by the present invention has the effects of passing electrochemically active molecules stored in a grapheme polymer porous microsphere through an ion membrane reaction cell and a semiconductor capacitor accumulator.

### Description of Related Arts

Looking forward to the development direction of the electric vehicles in the future, Lithium air-fueled battery and super fuel cells are generally believed by the automotive industry to be the development direction of the electric vehicles in the future. However, these batteries still have large technical problems and defects, and are not capable of meeting the requirements in market applications. It is well known that lithium-air fuel cells are mainly problematic in that during the reaction of the battery, a large amount of lithium peroxide (LiO₂) and carbonate are easily generated, and by-products formed are deposited at the discharge interface, which blocks charging of the battery and causing worse cycle ability and affects service life of the battery. The problem with super capacitors is that the battery has a low energy density and a large volume, so it is usually not suitable for small and medium-sized automobiles.

The new driving technology for electric vehicle engine disclosed in the present invention can meet the requirements of the current electric vehicle power and drive a motor with a power of 50 KW. The working principle of the battery is based on a liquid battery structure, and the graphene polymer porous microsphere material is prepared in advance as a solvent filled with positive and negative charges, and the solvent has two types: liquid powder and dry powder. The solvent is placed in a special ratio of positive and negative ion solutions in a certain proportion, and two independent circulating pumps can be used to control the flow rate of the positive and negative ion solutions into the same diaphragm reaction tank. The ionic membrane reaction tank is connected in parallel with the semiconductor capacitor accumulator. When the ionic solution enters the diaphragm reaction cell and the semiconductor capacitor accumulator at the same time, a current is generated to drive the motor to work.

If the charged solution completely loses power, the remaining battery solution can be recovered by a special factory, and the liquid battery material is recharged after activation by a specific device, so that the active material molecules stored in the graphene porous microspheres are restored to the original state.

The method for preparing a liquid battery material of the present patent has a higher energy density ratio than a general solid battery, and is generally several times higher. The method is very easy to apply. It can be refilled with enough charged ion solution at any time, which is suitable for the long-term battery life of pure electric vehicles.

The electric vehicle engine driver of the present invention is expected to have a working life of more than 15 years. Furthermore, graphene polymer porous microsphere materials and semiconductor capacitive engines can be mass-produced, and the manufacturing cost will be far lower than that of fuel. In particular, one technical advantage of the patent is that the graphene polymer porous microsphere material and the ionic solution after use can be completely recycled and reused by 100%, repeated charge and discharge, and there is no limit in cycle number. And in the recycling process, there is no pollution, no emissions, and there is environmental problem. The significance of this patent will help to develop the electric vehicle market, reduce CO₂ emissions, eliminate smog, improve air quality, and promote sustainable development of the green economy.

### SUMMARY OF THE PRESENT INVENTION

The new electric vehicle engine driving technology disclosed in the present invention adapts the requirements of modern environmental protection vehicles, can meet the requirements of automobile power and drive a motor with a power of 50 KW. Since the automobile battery in the present invention is in the form of a liquid charge, taking advantage that a large amount of active molecular material can be stored in a graphene polymer porous microsphere. The energy density of the battery of the present invention can be increased by several times compared with the conventional solid battery energy storage method. In particular, the charged solution placed in the fuel tank of the car can be replenished at any time without no limit on the number of cycles of the battery, which greatly increases the battery capacity of the car, and is very suitable for the endurance of the electric car.

The automotive semiconductor capacitive driving system of the present invention has a basic structure comprising a Faraday capacitor collector module mounted on a vehicle precursor, charged solution containing a large amount of graphene polymer porous microspheres, a diaphragm reaction tank, two fluid tanks respectively with a circulation pump and a motor driven by a front wheel and a rear wheel.

A basic structure of the Faraday semiconductor capacitor collector module comprises dozens of parallel semiconductor PN film materials wrapped to form a sealed current collector; a positive electrode and a negative electrode of graphene are provided between the semiconductor films and are isolated by electrical isolation ion membrane, wherein a container is made of polyethylene plastic, and connected to the ion membrane reaction tank, which is as shown in the drawing.

The Faraday semiconductor capacitor collector module is a new semiconductor product having charge and capacitance products with multi-layer double-sided PN junction operating characteristics, wherein positive charges and negative charges form a working circuit by a semiconductor reaction interface; wherein in the new molecular electrochemical energy storage device, while charging, Si ions are at the center of the polarization reaction, Li ions performs permeation migration. Thus the new molecular electrochemical energy storage device has higher voltage resistance than common capacitors, and is capable of performing large power discharge.

A energy storage mechanism of the Faraday semiconductor capacitor collector module is based on the Helmholtz dual-capacitor interface theory, which introduces a PN junction capacitor effect, which is capable of significantly increasing a capacitor interface potential and enhancing capacitor ratio of the battery; wherein an energy storage mechanism is introducing multi-layer semiconductor double-sided PN junction capacitor effect based on Helmholtz's dual-capacitor interface theory, which is capable of significantly increasing the capacitor interface potential and enhancing the capacitance ratio of a vehicle battery.

A critical characteristic of the present invention is to combine two types of a PN type and NP type semiconductor capacitor collector films and ion diaphragm reaction cell, so that the semiconductor PN junction capacitance effect of both sides is obtained; wherein by reverse charging, as the voltage rises, a charging depth gradually increases, which accordingly increases capacitance interface and capacitance, in such a manner that the charge collector module has a larger storage and discharge capability.

A first technical feature of the present invention is that two types of current collector graphene film of the PN type and the NP type adopt separate positive and negative electrode leads, and are connected with external power supply and load through an electrode exchange switch, rather than a simple ordinary wiring method.

A second technical feature of the present invention is a composite charging technology, which is completely different from a charging method of an ordinary battery; a special external intelligent control charging switch group is needed, in a same device, multiple electrode sets must be charged at the same time, so that multiple sets of capacitive effects can be generated at different electrical interfaces; which is a new technique of expanding specific capacity.

Pay special attention to a fact that charging must be reversed, and discharging process is needed to change to positive access. The discharge process is the same as the ordinary battery method, but it needs to be opened by switching off, the energy storage battery modules are connected in series/parallel to form a high-power energy storage discharger.

A third technical characteristic of the present invention is that the preparation of the battery separator material has characteristics of high temperature resistance, corrosion resistance and stability, strong ion penetration and good selectivity; the present invention adopts high-purity Al₂O₃ doped with quartz cellulose as a raw material to form a nano-amembrane material layer between the PN and NP composite films by epitaxial vapor deposition; wherein a material of the nano-amembrane material layer is a high insulator, and electrons are not capable of passing through, but in the microstructure, the nano-amembrane material layer is filled with fibrous microporous gaps, so the nano-amembrane material layer has selective passage and strong penetrating ability for certain ions.

The ion permeable membrane prepared in the present invention is capable of improving the quality of the liquid power battery, which is a key technology of the present invention; since the ion permeable membrane has characteristics of preventing liquid battery leakage current, potentials of the two sides of the ion membrane material is capable of being maintained in a relatively stable balancel; while charging, diaphragm material does not block ion permeation, so that the liquid battery is capable of performing ion migration rapidly. The principle is identical to ion diaphragm reaction tank.

A fourth characteristic of the present invention is that the liquid battery enhances mobility the positive ions and negative ions effects through a semiconductor PN junction capacitance effect; in a charging process, based on a semiconductor capacitance effect, a plurality of charge is adsorbed on a surface of the PN junction ion; during a discharging process, under actions of an electric field, charged ions pass through the insulating diaphragm layer, positive ion is penetrated into a cathode region, producing an electro-chemical reduction reaction like a battery, the liquid battery has unique energy storage and discharge cyclical performances, which are not limited by a number of cycles.

A first method for preparing Faraday semiconductor capacitor film, comprises steps of: taking high-purity SiH₄ and Li and Al ions as raw materials to vapor-deposit methacrylate ionization group materials on a surface of the graphene film to form a macroporous ion exchange resin skeleton to prepare a composite substrate, such as Li₉AlSi₃; wherein advantages of such a composite substrate is having high electrical conductivity like metal, and Si is in a reaction center of polarization, wherein Li ions are convenient for vacancy migration; the composite substrate has a large discharge specific capacity and a stable structure, and long-term cyclic charge and discharge have little impacts on volume change of the composite substrate.

A second method for preparing the Faraday semiconductor capacitor film of the present invention comprises: doping electron gas SiH₄ twice severely on a surface of the graphene substrate to form two silicon mask layers of a P-type and an N-type; wherein vapor deposition is usually carried out in industrial process, and introducing a mixture of P and H into a first reaction chamber to obtain an N-type film; a mixed gas of B and H is introduced into a second chamber to obtain a P-type membrane.

A third method for preparing the Faraday semiconductor capacitor current collector film, comprises steps of: pressing a P-type film and an N-type film into a vacuum operation box by electrostatic adsorption, and inner surfaces of the P-type film and the N-type film are tightly adhered in parallel to form a combination of two types of current collectors of the PN type and the NP type; wherein in general, a combined thickness of the current collector film is controlled to be less than 0.50 μm, and a monomer area is as large as possible, but is limited by mechanical strength and uniformity.

A fourth method for preparing a Faraday semiconductor capacitor current collector film, comprises steps of: vacuum sputtering outer surfaces of two current collector graphene films combination of a side of a non-silicon mask layer; preparing a nanocarbon crystal electrode layer on the side of non-silicon mask layer; then covering with a conductive inorganic molecular macroporous resin polymer having a thickness of 1-3 mm; which is beneficial to strengthen fluidity of the battery active material, increase a charge exchange space of the current collector, and improve the electrical conductivity and the electrical volume ratio.

In the driver module container, positive ionic liquid circulates in the P-type current collector region, and negative ionic liquid circulates in an N-type current collector region; when positive and negative charges carried by the positive ions and the negative ions are consumed, replacing with factory-specific recycling equipment for regenerative charging.

The characteristics and preparing method of positive and negative ionic liquid materials described in the present invention are described by another U.S. patent; however, the claims of the present invention comprises all charged ionic liquid materials that are used in an infusion manner.

As described above, the present invention uses a Faraday capacitor collector module to connect in parallel with an ionic membrane reaction tank to complement the charged solution method to form a new vehicle power source, so as to form endurance as convenient as refueling. Since the combined voltage of the patented battery module can reach 500V and the driving current is greater than 500 A, which can fully meet the normal driving requirements of small cars. In addition, the liquid battery material has a high energy density ratio, generally up to 500 Wh/kg. And by adding liquid charge to increase the power, it can be done in a few minutes. Therefore, this patented technology has forward-looking technical advantages and broad market application prospects, which has very positive social significance for the development of environmentally-friendly automotive batteries.

### BRIEF DESCRIPTION OF THE DRAWINGS

The FIGURE is a structure sketch view according to a preferred embodiment of the present invention.

### REFERENCE NUMBERS IN THE FIGURE IS AS FOLLOWS

1: P-type structure collector with positive ion solution circulation;
2: P-type collector structure lead;
3: N-type collector structure lead;
4: N-type structure collector with negative ion solution circulation;
5: ion permeable insulation film;
6: P-type structure collector with positive ion solution circulation;
7: P-type collector structure lead;
8: N-type collector structure lead;
9: N-type structure collector with negative ion solution circulation;
10: first ion solution pump;
11: second ion solution pump;
12: storage box with positive ion solution;
13: storage box with negative ion solution;
14: Faraday semiconductor capacitor driver package housing.

### DETAILED DESCRIPTION OF THE PREFERRED EMBODIMENT

The present invention is a semiconductor engine driving technology for electric vehicles, which is applied in a field of new energy for automobiles; the semiconductor engine of the present invention is configured to convert electrochemical energy stored in a liquid or dry powdered grapheme porous microsphere into automotive electric power; wherein a method of the present invention is equally applicable to various types of polymeric porous framework materials.

The technology of the present invention having a working principle completely different from a working principle of ordinary batteries, and does not use a battery stack active plate like an ordinary battery; wherein the reason is that there is no reversible chemical reaction on the electrode plate, but a semiconductor capacitive drive system is connected to an ion diaphragm reaction cell to generate current through ion exchange. The usual method is to charge a large amount of electrochemically active substance adsorbed in the graphene polymer porous microspheres using a proprietary device, and then vacuum dehydrate to prepare a dry powder solvent; with this charged dry powder solvent, it is easy to replace the liquid battery, and the charged dry powder can be added to supplement the electric energy at any time, thus greatly improving the endurance of the electric vehicle; the patented method is equally applicable to various types of injected charged molecular materials.

The automotive semiconductor capacitive driving system of the present invention has a basic structure comprising a Faraday capacitor collector module mounted on a vehicle precursor, charged solution containing a large amount of graphene polymer porous microspheres, a diaphragm reaction tank, two filling tanks respectively with a circulation pump and a motor driven by a front wheel and a rear wheel.

A basic structure of the Faraday semiconductor capacitor collector module comprises dozens of parallel semiconductor PN film materials wrapped to form a sealed current collector; a positive electrode and a negative electrode of graphene are provided between the semiconductor films and are isolated by electrical isolation ion membrane, wherein a container is made of polyethylene plastic, and connected to the ion membrane reaction tank, which is as shown in the drawing.

The Faraday semiconductor capacitor collector module is a new semiconductor product in which positive charges and negative charges form a working circuit by a semiconductor reaction interface; wherein the new molecular electrochemical energy storage device not only has the ability to store electric charge like a battery, but also has higher voltage resistance than common capacitors, and is capable of performing large power discharge.

A energy storage mechanism of the Faraday semiconductor capacitor collector module is based on the Helmholtz dual-capacitor interface theory, which introduces a PN junction capacitor effect, which is capable of significantly increasing a capacitor interface potential and enhancing capacitor ratio; wherein an energy storage mechanism is introducing multi-layer semiconductor double-sided PN junction capacitor effect based on Helmholtz's dual-capacitor interface theory, which is capable of significantly increasing the capacitor interface potential and enhancing the capacitance ratio of a vehicle battery.

A technical character of the present invention combines two types of a PN type and NP type semiconductor capacitor collector films and ion diaphragm reaction cell, so that the semiconductor PN junction capacitance effect of both sides is obtained; wherein by reverse charging, as the voltage rises, a charging depth gradually increases, which accordingly increases capacitance interface and capacitance, in such a manner that the charge collector module has a larger storage and discharge capability.

A first method for preparing Faraday semiconductor capacitor film, comprises steps of: taking high-purity SiH₄ and Li and Al ions as raw materials to vapor-deposit methacrylate ionization group materials on a surface of the graphene film to form a macroporous ion exchange resin skeleton to prepare a composite substrate, such as Li₉AlSi₃; wherein advantages of such a composite substrate is having high electrical conductivity like metal, and Si is in a reaction center of polarization, wherein Li ions are convenient for vacancy migration; the composite substrate has a large discharge specific capacity and a stable structure, and long-term cyclic charge and discharge have little impacts on volume change of the composite substrate.

A second method for preparing the Faraday semiconductor capacitor film of the present invention comprises steps of: doping electron gas SiH₄ twice severely on a surface of the graphene substrate to form two silicon mask layers of a P-type and an N-type; wherein vapor deposition is usually carried out in industrial process, and introducing a mixture of P and H into a first reaction chamber to obtain an N-type film; a mixed gas of B and H is introduced into a second chamber to obtain a P-type membrane.

A third method for preparing the Faraday semiconductor capacitor current collector film, comprises steps of: pressing a P-type film and an N-type film into a vacuum operation box by electrostatic adsorption, and inner surfaces of the P-type film and the N-type film are tightly adhered in parallel to form a combination of two types of current collectors of the PN type and the NP type; wherein in general, a combined thickness of the current collector film is controlled to be less than 0.50 μm, and a monomer area is as large as possible, but is limited by mechanical strength and uniformity.

A fourth method for preparing a Faraday semiconductor capacitor current collector film, comprises steps of: vacuum sputtering outer surfaces of two current collector graphene films combination of a side of a non-silicon mask layer; preparing a carbon nanocrystalline electrode layer on the side of non-silicon mask layer; then covering with a conductive inorganic molecular macroporous resin polymer having a thickness of 1-3 mm; which is beneficial to strengthen fluidity of the battery active material, increase a charge exchange space of the current collector, and improve the electrical conductivity and the electrical volume ratio.

A technical feature of the present invention is that two types of current collector graphene film of the PN type and the NP type adopt separate positive and negative electrode leads, and are connected with external power supply and load through an electrode exchange switch, rather than a simple ordinary wiring method.

A second technical feature of the present invention is a composite charging technology, which is completely different from a charging method of an ordinary battery; a special external intelligent control charging switch group is needed, in a same device, multiple electrode sets are charged at the same time, so that multiple sets of capacitive effects can be generated at different electrical interfaces; which is a new technique of expanding specific capacity, wherein pay special attention to a fact that charging must be reversed, and discharging process is needed to change to positive access. The discharge process is the same as the ordinary battery method, but it needs to be opened by switching off, the energy storage battery modules are connected in series/parallel to form a high-power energy storage discharger.

A third technical characteristic of the present invention is that the preparation of the battery separator material has characteristics of high temperature resistance, corrosion resistance and stability, strong ion penetration and good selectivity; the present invention adopts high-purity Al₂O₃ doped with quartz cellulose as a raw material to form a nano-amembrane material layer between the PN and NP composite films by epitaxial vapor deposition; wherein a material of the nano-amembrane material layer is a high insulator, and electrons are not capable of passing through, but in the microstructure, the nano-amembrane material layer is filled with fibrous microporous gaps, so the nano-amembrane material layer has selective passage and strong penetrating ability for certain ions.

The ion permeable membrane prepared in the present invention is capable of improving the quality of the liquid power battery, which is a key technology of the present invention; since the ion permeable membrane has characteristics of preventing liquid battery leakage current, potentials of the two sides of the ion membrane material is capable of being maintained in a relatively stable equilibrium; while charging, diaphragm material does not block ion permeation, so that the liquid battery is capable of performing ion migration rapidly.

A fourth characteristic of the present invention is that the liquid battery enhances mobility the positive ions and negative ions effects through a semiconductor PN junction capacitance effect; in a charging process, based on a semiconductor capacitance effect, a plurality of charge is adsorbed on a surface of the PN junction ion; during a discharging process, under actions of an electric field, charged ions pass through the insulating diaphragm layer, positive ion is penetrated into a cathode region, producing an electrochemical reduction reaction like a battery, the liquid battery has unique energy storage and discharge cyclical performances, which are not limited by a number of cycles.

In the driver module container, positive ionic liquid circulates in the P-type current collector region, and negative ionic liquid circulates in an N-type current collector region; when positive and negative charges carried by the positive ions and the negative ions are consumed, replacing with factory-specific recycling equipment for regenerative charging.

The characteristics and preparing method of positive and negative ionic liquid materials described in the present invention are described by another U.S. patent; however, the claims of the present invention comprises all charged ionic liquid materials that are used in an infusion manner;

wherein in summary, the new electric vehicle engine driver technology disclosed in the present invention combines a Faraday semiconductor capacitive collector module and a liquid ion recycling method to form a power source of new-generation vehicles, which can provide identical powerful driving force as fuel. The technical feature of the present invention is that the combination voltage of the battery module can reach 500V, and the driving current is greater than 500 A, which can fully meet the normal driving requirements of small and medium-sized cars. In particular, the high energy density ratio of the battery reaches 500 Wh/kg or more, and the present invention is easy to replace the negative liquid ion active material which is fully charged with electric power;

wherein based on that the automotive battery of the present invention is in the form of a liquid charge, a large amount of active molecular materials can be stored in a graphene polymer porous microsphere. Therefore, compared with the conventional solid battery energy storage method, the energy density of the automobile battery can be improved by several times. And the charged solution placed in the fuel tank of the car can be replenished at any time. There is no limit on the number of cycles of the battery, which greatly increases the battery capacity of the car and is suitable for the life of the electric car;

wherein the present invention has unique technical advantages and broad market application prospects, which has very positive social significance for promoting the development of batteries of global electric vehicles.

In ordinary electric vehicles, more than 10 sets of new battery packs manufactured by the present invention can be utilized synchronously, and the voltage is boosted to 500V by the inverter.

The battery manufactured in the present invention is capable of driving 12A×4 Prius motors respectively, wherein an average driving power is 6 KW.

Although stacking the battery cells is capable of increasing the battery capacity, the overall battery capacity of the present invention is mainly determined by being stored in the fuel tank.

An amount and density of porous polymerized electrification is as follows. Generally, 60 liters of positive and negative charge fuel tanks are equipped. The battery capacity of the whole vehicle can reach 120 kWh, that is, all liquid battery solutions are replaced again after 1000 km of normal driving.

One skilled in the art will understand that the embodiment of the present invention as shown in the drawings and described above is exemplary only and not intended to be limiting.

It will thus be seen that the objects of the present invention have been fully and effectively accomplished. Its embodiments have been shown and described for the purposes of illustrating the functional and structural principles of the present invention and is subject to change without departure from such principles. Therefore, this invention includes all modifications encompassed within the spirit and scope of the following claims.

What is claimed is:

1. An automotive semiconductor capacitive driving system comprising: a Faraday capacitor collector module mounted on a vehicle precursor, charged solution containing a large amount of graphene polymer porous microspheres, a diaphragm reaction tank, two filling tanks respectively with a circulation pump and a motor driven by a front wheel and a rear wheel.

2. The automotive semiconductor capacitive driving system, as recited in claim 1, wherein a basic structure of the Faraday semiconductor capacitor collector module comprises dozens of parallel semiconductor PN film materials wrapped to form a sealed current collector; a positive electrode and a negative electrode of graphene are provided between the semiconductor films and are isolated by electrical isolation ion membrane, wherein a container is made of polyethylene plastic, and connected to the ion membrane reaction tank.

3. The automotive semiconductor capacitive driving system, as recited in claim 1, wherein the Faraday semiconductor capacitor collector module is a new semiconductor product in which positive charges and negative charges form a working circuit by a semiconductor reaction interface; wherein the new molecular electrochemical energy storage device not only has the ability to store electric charge like a battery, but also has higher voltage resistance than common capacitors, and is capable of performing large power discharge.

4. The automotive semiconductor capacitive driving system, as recited in claim 1, wherein an energy storage mechanism of the Faraday semiconductor capacitor collector module being based on the Helmholtz dual-capacitor interface theory, which introduces a PN junction capacitor effect, which is capable of significantly increasing a capacitor interface potential and enhancing capacitor ratio; wherein an energy storage mechanism is introducing multi-layer semiconductor double-sided PN junction capacitor effect based on Helmholtz's dual-capacitor interface theory, which is capable of significantly increasing the capacitor interface potential and enhancing the capacitance ratio of a vehicle battery.

5. The automotive semiconductor capacitive driving system, as recited in claim 1, wherein two types of a PN type and NP type semiconductor capacitor collector films and ion diaphragm reaction cell are combined, so that the semiconductor PN junction capacitance effect of both sides is obtained; wherein by reverse charging, as the voltage rises, a charging depth gradually increases, which accordingly increases capacitance interface and capacitance, in such a manner that the charge collector module has a larger storage and discharge capability.

6. The automotive semiconductor capacitive driving system, as recited in claim 1, wherein a technical feature of the present invention is that two types of current collector graphene film of the PN type and the NP type adopt separate positive and negative electrode leads, and are connected with external power supply and load through an electrode exchange switch, rather than a simple ordinary wiring method.

7. A method for preparing Faraday semiconductor capacitor film, comprising steps of: taking high-purity SiH₄ and Li and Al ions as raw materials to vapor-deposit methacrylate ionization group materials on a surface of the graphene film to form a macroporous ion exchange resin skeleton to prepare a composite substrate, such as Li₉AlSi₃; wherein advantages of such a composite substrate is having high electrical conductivity like metal, and Si is in a reaction center of polarization, wherein Li ions are convenient for vacancy migration; the composite substrate has a large discharge specific capacity and a stable structure, and long-term cyclic charge and discharge have little impacts on volume change of the composite substrate.

8. A method for preparing the Faraday semiconductor capacitor film comprising steps of: doping electron gas SiH₄ twice severely on a surface of the graphene substrate to form two silicon mask layers of a P-type and an N-type; wherein vapor deposition is usually carried out in industrial process, and introducing a mixture of P and H into a first reaction chamber to obtain an N-type film; a mixed gas of B and H is introduced into a second chamber to obtain a P-type membrane.
